(19) United States
(12) Patent Application Publication
(10) Pub. No.: US 2003/0222668 A1
(43) Pub. Date: Dec. 4, 2003

(54) Method for producing micro probe tips

(75) Inventors: Wen-Ching Hung, Taipei Hsien (TW); Howard Hsu, San Jose, CA (US)

Correspondence Address: HOGAN & HARTSON L.L.P., 500 S. GRAND AVENUE, SUITE 1900, LOS ANGELES, CA, 90071-2611, US

(73) Assignee: SCS Hightech, Inc.

(21) Appl. No.: 10/387,332

(22) Filed: Mar. 12, 2003

(30) Foreign Application Priority Data
Mar. 13, 2002 (TW) 091104650

(51) Int. Cl. B05D 5/12; G01R 31/02

(52) U.S. Cl. 324/762; 324/758; 29/832; 29/846; 427/97

(57) ABSTRACT

Micro-fabrication forms a plurality of stiff vertical micro probes on the front surface of a ceramic substrate and a plurality of contacts on the back surface of the ceramic substrate. Photolithography, various etching technologies and electroplating are used to form the micro probes on the surface of the ceramic substrate. The produced micro probes are mechanically strong and consequently have a long duty life. Moreover, the probes can be arranged into a high-density planar array to conform to the newest integrated circuit devices which have dense I/O terminal arrays.

### PRIORITY

This application claims priority from Taiwanese patent application 091104650, filed Mar. 13, 2002, which application is incorporated by reference in its entirety.

### BACKGROUND

1. Field of the Invention

The present invention relates to a method for producing probe cards for testing integrated circuits, more particularly the process for forming micro probes on a ceramic substrate for testing integrated circuits, and also to the process for testing one or more dies on an integrated circuit wafer using such a probe card.

2. Description of the Related Art

Testing integrated circuit (“IC”) characteristics including reliability of ICs is indispensable to the semiconductor industry. As IC manufacturing technology advances, ICs perform better and are able to work at higher frequencies with ever smaller die sizes. The technology and equipment for IC testing needs to advance correspondingly. The number and density of the probes on a testing probe card should conform with the number and density of input/output (“I/O”) terminals of the ICs to be tested. All the lines and leads from the probes to the automatic test equipment (“ATE”) that generates and processes testing signals should be able to work at higher frequencies and maintain low noise to render accurate testing results. Besides, the cost of testing is an important component of the total cost of producing ICs. Therefore it is important to improve the performance of testing and to reduce its cost.

Testing of an IC's characteristics and its reliability is carried out after the IC die has been packaged by sending and picking up test signals via the pins extending out of the IC package. Such a process does not sort out bad dies before packaging and thus wastes time and money when bad dies are packaged. Manufacturing wafers consumes the most time in the process of manufacturing IC products. In a typical process flow the failure rate of the ICs is only known at the last stage. It is consequently normal to produce a number of surplus wafers at the first stage of IC production in anticipation of failures because it is generally not acceptable to start replacement wafer production when the IC failure rate is known. The result is that a manufacturer will keep a larger stock of wafers on hand, which increases costs.

Multi-chip modules have become more popular as advanced packaging technology has become available. In a multi-chip module any bad chip will result in the discard of the entire module. In a conventional process, testing is not done before the chips are packaged but is applied to the packaged multi-chip module. The testing thus experiences the greater complexity of the module and achieves less reliable results. The result is higher testing costs, longer research and development cycles and costs, and a higher risk of returned goods. If individual dies were sorted before they were packaged, testing of the packaged multi-chip module would only need to identify damage caused by the packaging process, limiting the above-mentioned drawbacks.

Wafer sort technologies that test individual dies within a completed integrated circuit wafer before packaging have been developed to address the problems associated with traditional IC testing technology. FIGS. 20a and 20b illustrate a conventional wafer sort apparatus that uses cantilever type probes. FIG. 20a shows the bottom side of a probe card 10 that includes a substrate 11 with a plurality of probes 12 mounted on the bottom side of the substrate 11. The probes 12 are arranged in a fan-shape with a first end 121 of each probe 12 extending through a resin plate 13. The resin plate 13 has an opening in its central portion and is tightly attached to the substrate 11 by adhesive. The arrangement of the probes 12 corresponds to the positions of the I/O terminals (bonding pads) 21 of the integrated circuit 20 to be tested, which is to be located under the probes 12. During testing the second ends 122 of the probes 12 are aligned to contact the I/O terminals 21. The substrate 11 has a plurality of leads 14 each having a first end 141 inserted in the resin plate 13 where the first end 141 is connected to the first end 121 of each probe 12. The second end 142 of each lead 14 extends outward and is soldered to the substrate 11. To provide connection with the testing circuits, the substrate 11 comprises a plurality of terminals (not shown in the figures) electrically linked to the leads 14 via electrical lines on the surface of and inside the substrate 11.

The illustrated probe card has several drawbacks. First, using this probe card to test a die requires that the bonding pads which act as the I/O terminals of the die be located only on the circumference of the die. Secondly, due to its structural strength requirement, the cantilever type probes 12 are generally made relatively thick in a manner that limits the density of the probes 12 on the card. Consequently the number of I/O terminals of the die to be tested may also be limited or the die might have to be made over-sized to allow for adequate I/O terminals and testability. Thirdly, cantilever type probe cards have limitations for high frequency testing. Each probe 12 combined with lead 14 forms a one to three inch-long unshielded electric wire and these electric wires are closely spaced, extending substantially in parallel. This results in serious electromagnetic interference (“EMI”) when high frequency test signals are applied. Moreover, the different lengths of these wires also causes impedance mismatches that are detrimental to high frequency access time testing.

Apart from the above-mentioned cantilever type probe cards, wafer sort apparatus of different designs have been disclosed, including the flexible membrane probe device described in “Flexible Contact Probe”, IBM Technical Disclosure Bulletin, October 1972, page 1513. The device comprises a flexible dielectric film having terminals that are suited to making electrical contact with pads on integrated circuits. The terminals are connected to the flexible wires of the test electronics. The major problem of such a device is that the dimensional stability of the membrane is not sufficient to allow contacts to be made to pads on a full wafer during a burn-in temperature cycle. Other disadvantages of conventional wafer sort systems are discussed in the following detailed description.

### SUMMARY OF THE PREFERRED EMBODIMENTS

An aspect of the present invention provides a method for producing a plurality of stiff vertical micro probes on a probe card adapted for accurately testing integrated circuit devices with high frequency signals.

Another aspect of the present invention provides a method for producing a large number of stiff vertical micro probes on a probe card adapted for testing integrated circuit devices with reduced sizes or with denser I/O terminals.

Still another aspect of the present invention provides a method for producing a large number of stiff vertical micro probes on a probe card adapted for testing integrated circuit devices having I/O terminals distributed over circumference and the central area of an IC die adapted for mounting to a printed circuit board using flip chip technologies.

Still another aspect of the present invention provides a method for producing a large number of stiff vertical micro probes on a probe card that is durable and has a simple structure.

A further aspect of the present invention provides a method for producing a large number of stiff vertical micro probes on a probe card with a low failure rate.

A still further aspect of the present invention provides a method for mass-producing a large number of stiff vertical micro probes on a probe card in shorter time.

How the foregoing are achieved will be discussed in the following with reference to the illustrating drawings, which form a part of the present disclosure.

### BRIEF DESCRIPTION OF THE DRAWINGS

FIGS. 1-19 are cross-sectional views of the materials used and their disposition during various stages of a preferred process in accordance with the present invention.

FIG. 20a is a perspective view of a conventional cantilever type probe card.

FIG. 20b is a cross-sectional view of the conventional cantilever type probe card shown in FIG. 20a.

FIGS. 21a, 21b and 21c illustrate the bottom side of a vertical probe card made with a preferred process consistent with aspects of the present invention.

FIG. 22 is a cross-sectional views of the multi-layer ceramic substrate made with a preferred process consistent with aspects of the present invention.

### DETAILED DESCRIPTION OF THE PREFERRED EMBODIMENTS

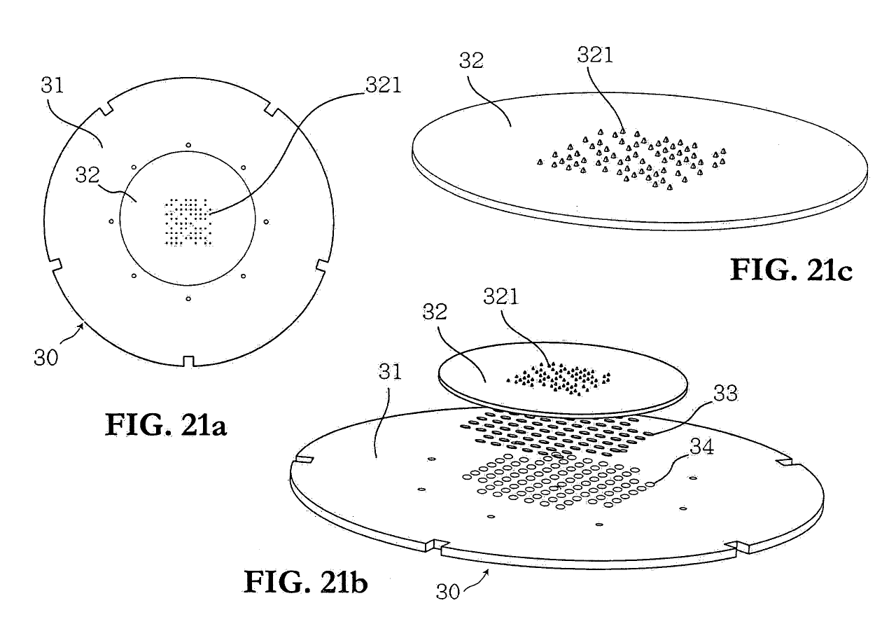

FIG. 21a is a bottom view of a vertical probe card 30 according to an implementation of an aspect of the present invention. The vertical probe card 30 comprises a printed circuit board 31 with a multi-layer ceramic substrate 32 mounted on the central portion of the board 31. The multi-layer ceramic substrate 32 has an array of stiff vertical probes 321 on its bottom surface. FIG. 21b provides an exploded perspective view of the vertical probe card 30, showing that the multi-layer ceramic substrate 32 is soldered to the printed circuit board 31 through solder pads 33 and solder bumps 34 using surface mount technology. FIG. 21c is an enlarged perspective view showing the arrangement of the vertical probes 321 on the bottom surface of the multi-layer ceramic substrate 32.

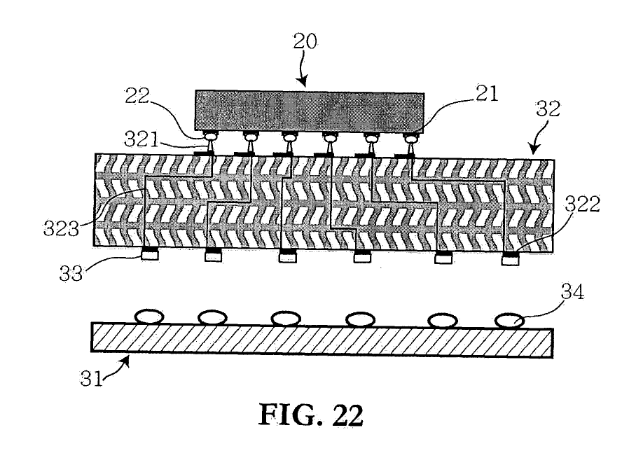

Now referring to FIG. 22, each solder pad 33 contacts a solder bump 34 to connect the bump through internal connections to a contact 322 on the top surface of the multi-layer ceramic substrate 32. The illustrated structure electrically connects the printed circuit (“PC”) board 31 to the probes 321 on the surface of the multi-layer ceramic substrate 32 through its internal lines 323. On the other side, the tips of the probes 321 contact the solder bumps 22 provided on the I/O terminals (bonding pads) 21 of the integrated circuit 20 to be tested.

The vertical probes 321 on the surface of the ceramic substrate 32 most preferably are formed by photolithography and electroplating techniques of the type employed in wafer processing. Therefore the size and the pitch of the vertical probes 321 can be reduced to a very small scale. The difference between the pitch of the vertical probes 321 and that of the vias is relatively small so the lengths of the horizontal redistribution lines are limited. Therefore the overall EMI generated from the unshielded lines is very low. As a result, the probe card 30 is suitable and advantageous for very high frequency testing.

0.13 micron process technology is becoming mainstream in current production of semiconductors. As the semiconductor manufacturing technology advances, the size of the transistors in an integrated circuit device has been reduced and individual IC devices contain more and more transistors and have more and more functions. As a consequence, the number of I/O terminals for an IC is typically increased. Traditional designs in which the I/O terminals are arranged in two rows or along the four edges of a die generally cannot meet the newest demands. Flip chip technology has been developed in response to the need for additional I/O terminals. Flip chip technology provides I/O terminals for an IC in an array over one surface of the IC and the I/O terminals are provided with solder bumps on them for mounting the IC to a PC board. In the past few years, IC packaging technology has evolved from QFP, to BGA, then to μBGA and now to wafer level packaging. The I/O terminals of an IC are thus not limited to the borders of the chip any more but may be arranged as an array of multiple columns and multiple rows arranged over a surface. Another factor which favors flip chip technology is that it can reduce EMI and thus facilitates higher frequency applications.

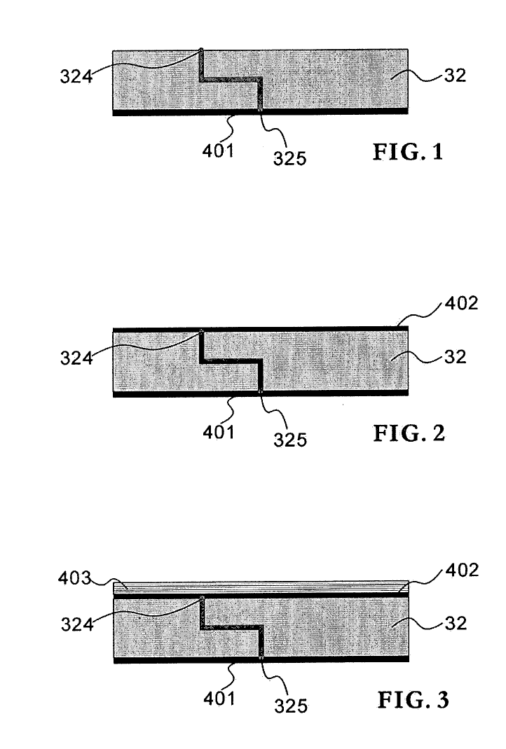

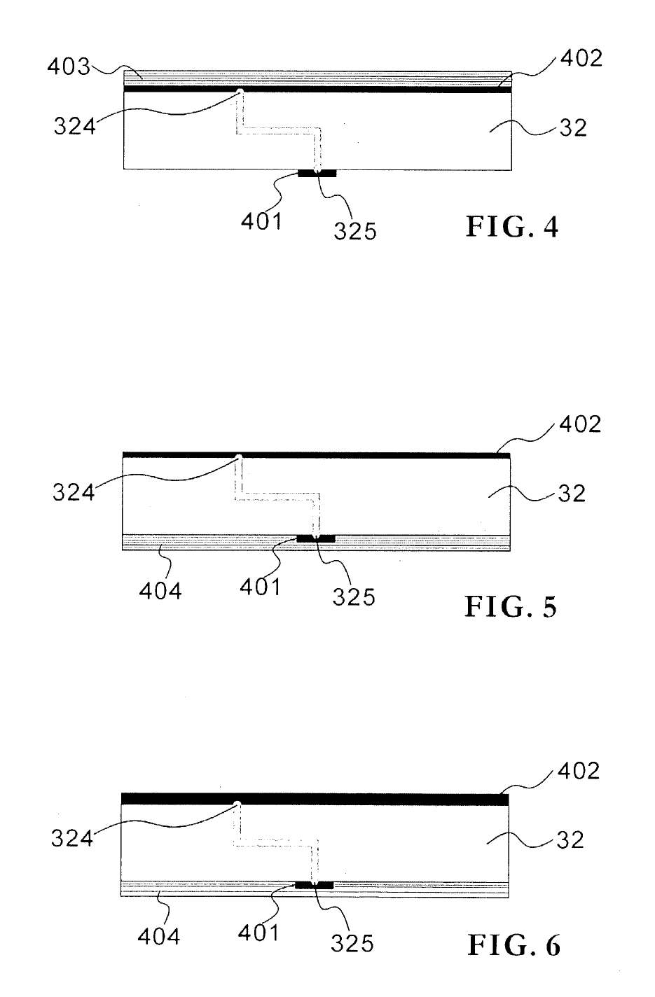

FIGS. 1-3 illustrate initial steps in a preferred process in accordance with an aspect of the present invention for forming micro probe tips on a ceramic substrate. First a layer of tungsten and then a layer of aluminum are sequentially sputtered on the back surface of the multi-layer ceramic substrate 32 to form a contact-pad layer 401. Sputtering or another form of physical vapor deposition (PVD) technology is particularly preferred, especially those forms of PVD that do not provide highly chemically reactive species to the deposition surface and instead effect a physical atomic transport. The contact-pad layer 401 connects to a plurality of exposed terminals 325 of the internal lines buried in the multi-layer ceramic substrate 32. Then a thin layer of tungsten 402 is sputtered on the front surface of the multi-layer ceramic substrate 32 by physical vapor deposition technology as shown in FIG. 2. A layer of polymer such as polyimide is formed on top of the tungsten layer 402 as a first temporary protective film 403 as shown in FIG. 3. Then the ceramic substrate 32 is laid back-side up and the unwanted portion of the contact-pad layer 401 is removed with photolithography and etching process to form the desired contact pads (also numbered with 401 in FIG. 4 and in the following description and figures) on the back surface of the ceramic substrate 32. The contact pads 401 will be electroplated with copper and become the solder pads 33 shown in FIG. 21b. The first temporary protective film 403 functions to protect the tungsten layer 402 and the terminals 324 (made of silver epoxy) of the underlying internal lines. Because the surface of the protective film 403 is finer than the original surface of the tungsten layer 402, it helps the adhesion of the ceramic substrate 32 to the machine table on application of vacuum or suction.

Referring now to FIG. 5, a layer of polymer such as polyimide is formed on the back surface of the ceramic substrate 32 as a second temporary protective film 404, to protect the contact pads 401 and the terminals 325 (made of silver epoxy) of the underlying internal lines. As explained before, the second temporary protective film 404 also helps hold the ceramic substrate 32 on the machine table on application of vacuum or suction because it provides a finer and more even surface. The ceramic substrate 32 is then turned over for the following processes on its front side. The first temporary protective film 403 is removed. Referring now to FIG. 6, more tungsten is deposited on the previously formed tungsten layer 402 using a chemical vapor deposition (CVD) process. Then the surface of the tungsten layer 402 is polished with a chemical mechanical polishing (CMP) process.

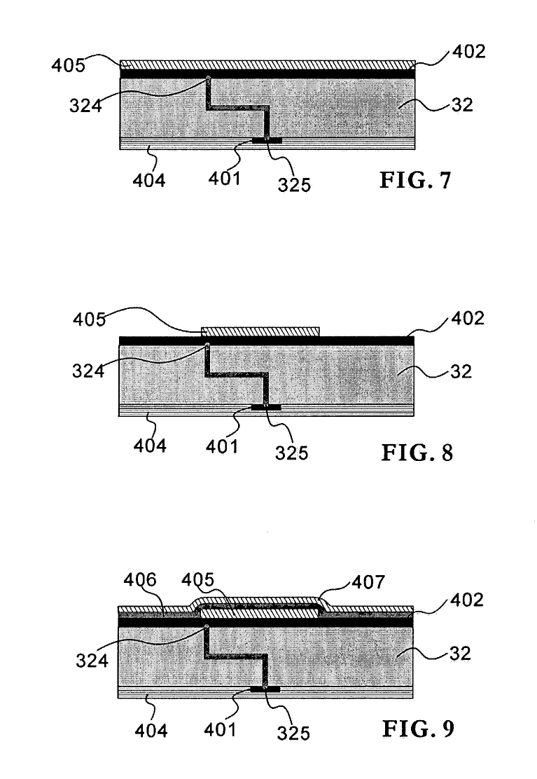

In case the tungsten layer 402 has holes worn through after the chemical mechanical polishing process, for example because the surface of the ceramic substrate 32 beneath it is too rough, it may be desirable to sputter a thin layer of tungsten on the tungsten layer 402 before carrying out the following processes. Referring now to FIG. 7, a layer of copper 405 is sputtered on the tungsten layer 402 with physical vapor deposition (PVD) process. The copper layer 405 is to be fabricated into redistribution lines (RDL) on the front surface of the ceramic substrate 32. The tungsten layer 402 is to function as the common cathode conductor for multiple micro probes 321 to be formed by electroplating.

Tungsten preferably is chosen to make the common conductor layer 402 for subsequent electroplating, with the tungsten most preferably deposited with both PVD and CVD processes, as explained below. The surface of ceramic is so rough that it is very difficult to plate ceramic with a metal layer that has a smooth and even surface. If ceramic were plated with a metal layer by PVD process alone, the crevices on its surface would in many instances not be filled in. Using CVD to deposit tungsten can resolve this problem. Up to the present, there is no known method of depositing copper with a CVD process but tungsten can be easily deposited with a CVD process. Because it can be deposited to form an even surface, tungsten preferably is chosen to be deposited with a CVD process to make the common conductor layer for electroplating. However, if tungsten were deposited directly on the ceramic substrate 32 by a CVD process, the chemical gas used in the CVD process would corrode the surface of the ceramic substrate 32. Therefore, in a preferred implementation of a process according to the present invention, a PVD process preferably is first employed to sputter a thin layer of tungsten covering the surface of the ceramic substrate 32. Preferably then a CVD process is employed to deposit more tungsten and form a conductor layer with a more even top surface.

After the deposition of the copper layer 405 has been completed, it is patterned into redistribution lines (RDL) on the surface of the ceramic substrate 32 by photolithography and wet etching process. An end of each completed redistribution line 405 is connected to a terminal 324 while the other end terminates at a position where a micro probe 321 is to be formed. Referring now to FIG. 9, a layer of chromium is sputtered by a PVD process on the front surface of the ceramic substrate 32 where the redistribution lines 405 are formed, as a protecting layer 406 of the redistribution lines 405. Then a layer of copper is sputtered again by a PVD process on the protecting layer 406 to form an adhering layer 407 between the chromium made protecting layer 406 and the micro probes 321 yet to be formed, which will be made of nickel or nickel alloy. The function of the protecting layer 406 is to isolate the copper-containing redistribution lines 405 which can be easily oxidized, from the coming harsh processing environments. The copper-containing adhering layer 407 preferably is used because nickel, which is the major composition of the micro probes 321, has poor adhesion to the chromium preferably used for the protecting layer 406, and that copper adheres well to either of them.

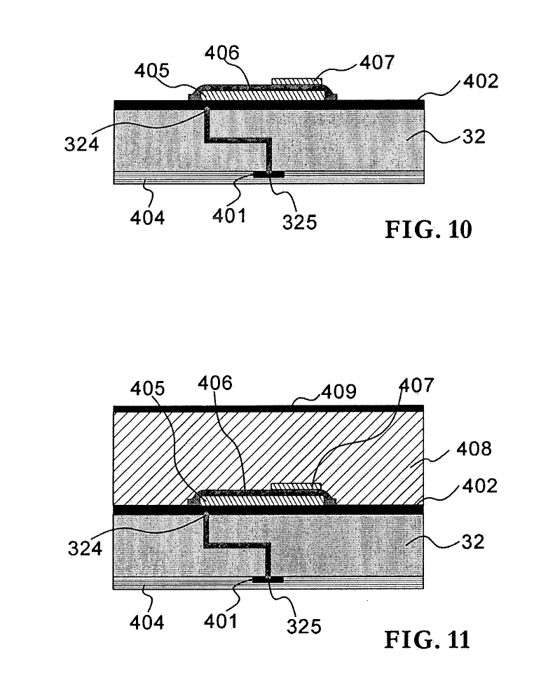

Referring now to FIG. 10, the adhering layer 407 is patterned by photolithography and wet etching processes into junction pads 407 each with a preferred surface area substantially identical to the footprint of a micro probe 321 to be formed. The protecting layer 406 is patterned into shapes just enough to fully cover the redistribution lines 405. This patterning is also accomplished by photolithography and wet etching processes.

Referring to FIG. 11, a sacrificial layer 408 is applied on the front surface of the ceramic substrate 32. The thickness of the sacrificial layer 408 substantially equals the height of the micro probes 321 to be formed. The material of the sacrificial layer 408 is most preferably selected to be compatible with and capable of sustaining the subsequent manufacturing processes including PVD, photolithography, etching and electroplating. Most preferably the sacrificial layer 408 is easily removable after the completion of the micro probes 321. On top of the sacrificial layer 408, a thin layer of tungsten is plated by PVD technology. The thin layer of tungsten is provided to be made into a mask 409 for use in a subsequent dry etching process.

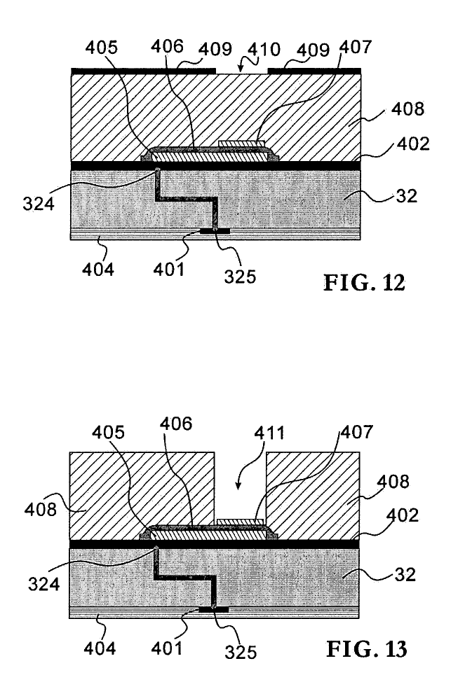

Referring now to FIG. 12, a photomask is formed over the mask 409 by photolithography and etching process. Then the mask 409 is etched through the photomask into through holes 410 at positions where the micro probes 321 are to be formed. The sacrificial layer 408 is then dry-etched into electroplating cavities 411 (shown in FIG. 13) formed by the etchant etching through the through holes 410.

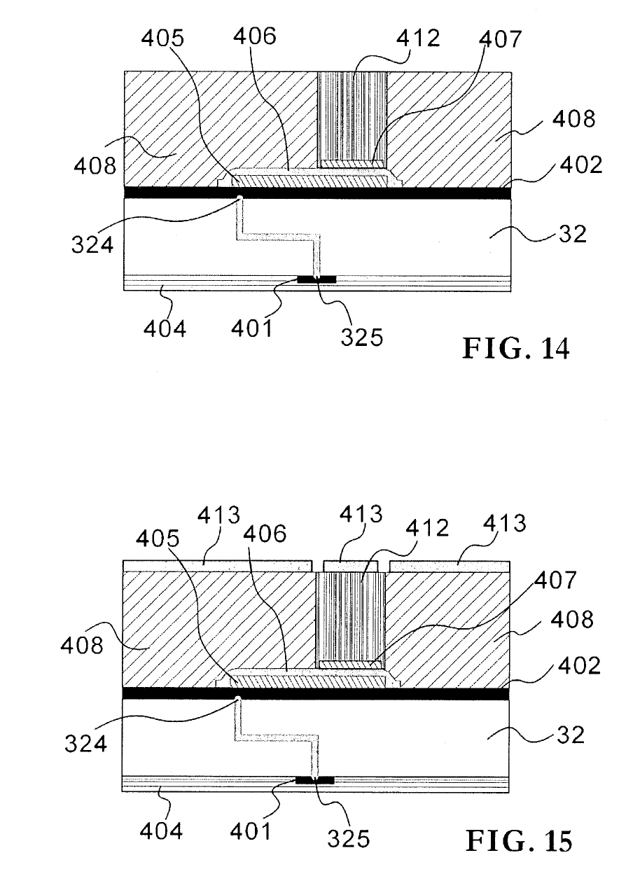

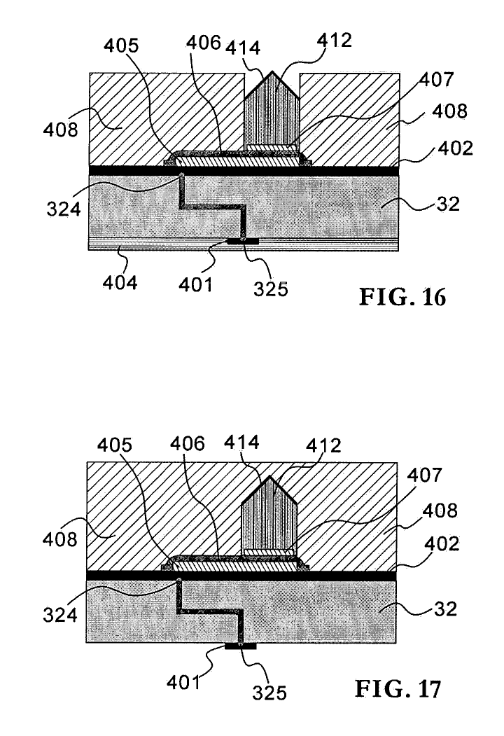

Before the electroplating process, the copper-containing junction pads 407 at the bottom of the electroplating cavities 411 are pickled and activated to obtain clean joining surfaces. Acid prickling is a preferred process for cleaning the exposed metal surface and activation prepares the surface for electroplating, including limiting oxide formation. Then the ceramic substrate 32 is put in an electroplating tub with an electroplating solution containing nickel ions. Optionally, as dictated by the various electrical property requirements of the micro probes 321, ions of other metals such as tungsten or cobalt can also be added to the electroplating solution to produce micro probes 321 of nickel-tungsten alloy or nickel-cobalt alloy. The conductor layer 402 is connected to the negative potential in the electroplating system and, when electric current is on, nickel (or nickel alloy) is deposited on the exposed metal surfaces of the ceramic substrate 32, namely the junction pads 407 at the bottom of the electroplating cavities 411. After a period of the electroplating process, the deposited nickel (or nickel alloy) reaches the same level as the top surface of the sacrifice layer 408 and fills up the electroplating cavities 411, forming the base material 412 of the micro probes 321, as shown in FIG. 14.

Referring now to FIG. 15, a layer of thick film photoresist material is applied over the top of the sacrificial layer 408 and of the base material 412 of the micro probes 321. The thick film photoresist layer is etched to become a tapering mask 413 containing a plurality of ring-shaped openings laid over and conforming to the circumferences of the top surface of the base materials 412. The base materials 412 are then wet-etched with the tapering mask 413. Due to the isotropic behavior of the wet etchant, the top portion of the base materials 412 becomes tapered or have a pointed tip.

After the pointed tips have been completed, they may be plated with rhodium to enhance their hardness, and consequently their wear resistance, and to protect them from oxidization. A further sacrificial layer made of polymer such as polyimide is then applied on the front side of the ceramic substrate 32 to protect the exposed tips of the micro probes 321 in the next process on the back side of the ceramic substrate 32. Optionally the polymer sacrificial layer can be replaced by a covering board. Referring to FIG. 17, the second temporary protective film 404 is removed. A thick layer of copper is sputtered on the back surface of the ceramic substrate 32 including the contact pads 401 and then is patterned into spots just covering the contact pads 401 by photolithography and wet etching (this process is not shown in the figures), thus forming the solder pads 33 shown in FIG. 21b.

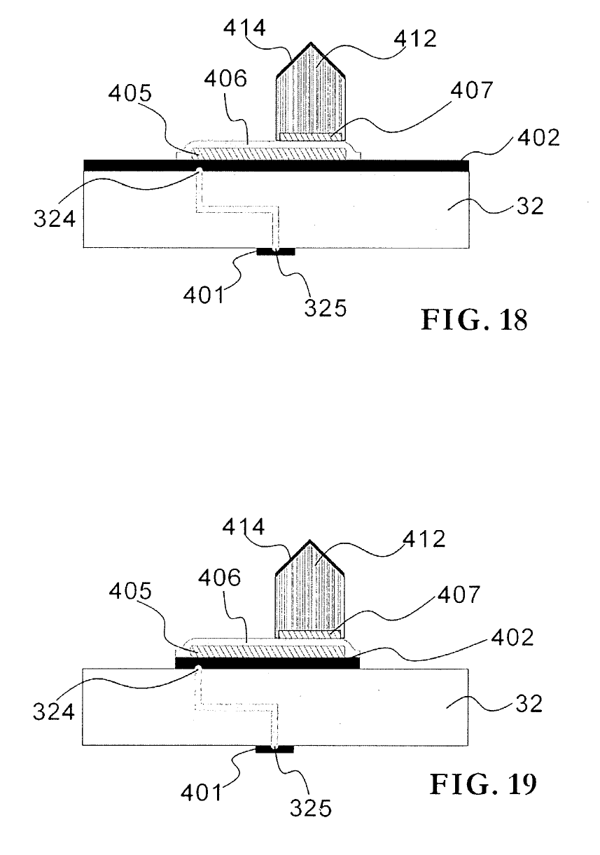

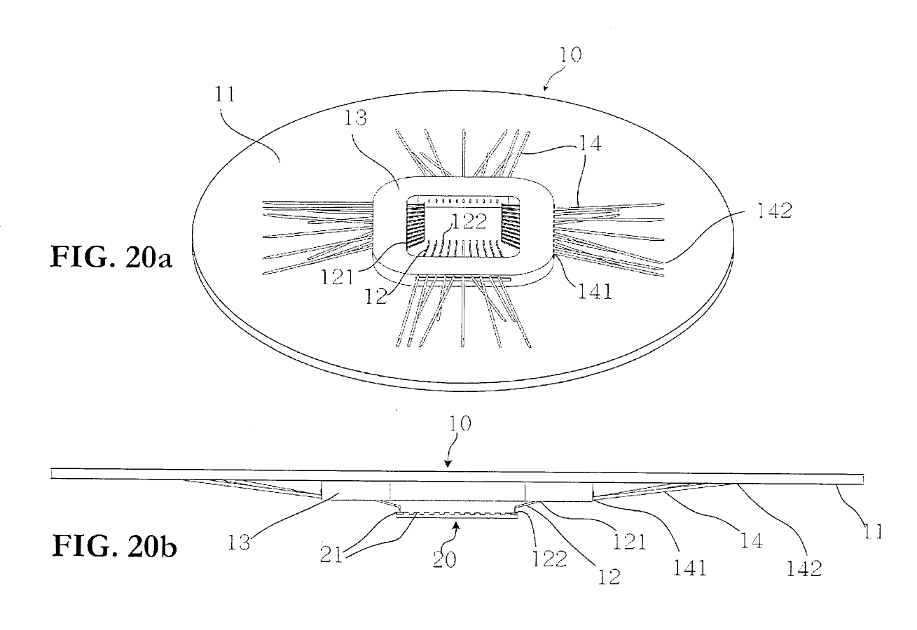

Referring to FIG. 18, the sacrificial layer 408 on the front side of the ceramic substrate 32 is removed. The ceramic substrate 32 is then put in a tungsten dry etch machine using SF₆ as an etchant to remove the exposed portions of the tungsten made conductor layer 402, as illustrated in FIG. 19. Finally, the ceramic substrate 32 comprising the micro probes 321 is fast annealed to enhance the overall mechanical strength.

The present invention has been described in terms of certain preferred embodiments thereof. Those of ordinary skill in the art will appreciate that various modifications might be made to the embodiments described here without varying from the basic teachings of the present invention. Consequently the present invention is not to be limited to the particularly described embodiments but instead is to be construed according to the claims, which follow.

1. A method for producing a plurality of micro probes on a front surface of a ceramic substrate and a plurality of contacts on its back surface, comprising:
providing a multi-layer ceramic substrate having internal electrical circuits with terminals exposed on both the surfaces thereof;
forming a metal contact-pad layer on the back surface of the ceramic substrate, the contact-pad layer connecting to the terminals exposed on the back surface;
forming a metal conductor layer on the front surface of the ceramic substrate, the conductor layer connecting to the terminals exposed on the front surface and being prepared for connecting to a negative electrical source through multiple electrodes in a later electroplating process in which the micro probes will be simultaneously formed;
patterning the contact-pad layer into individual contact pads covering the terminals exposed on the back surface with photolithography and etching process;
forming a metal redistribution line layer on the conductor layer;
patterning the redistribution line layer into desired redistribution lines with photolithography and etching process;
forming a sacrificial layer covering the front surface of the ceramic substrate and the redistribution lines;
forming a dry etch mask layer covering the sacrificial layer;
patterning the dry etch mask layer with photolithography and etching process into a plurality of through holes corresponding to a projection of the micro probes onto a surface of the sacrificial layer;
dry etching the sacrificial layer through the dry etch mask to form a plurality of vertical cavities reaching the redistribution lines;
electroplating metal in the vertical cavities on the redistribution lines exposed at the bottom of the vertical cavities through the conduction of the conductor layer until the metal fills up the vertical cavities;
applying a layer of thick film photoresist on top of the sacrifice layer and the metal deposited in the vertical cavities;
patterning the thick film photoresist into ring-shaped openings laid over and conforming to the circumferences of the top surface of the metal deposited in the vertical cavities;
wet etching the metal deposited in the vertical cavities through the ring-shaped openings of the thick film photoresist to taper the top portion of the metal thus forming the micro probes to have at least partially tapered tips;
removing the thick film photoresist;
removing the sacrificial layer; and
removing the conductor layer not covered by the redistribution lines.

2. The method of claim 1, wherein when one of either surface of the ceramic substrate is being treated with any of the processes including photolithography, etching, electroplating, chemical mechanical polishing, pre-electroplating activation and pickling, the opposite surface of the ceramic substrate is covered by a protective layer.

3. The method of claim 1, wherein a copper layer is formed on each of the contact pads.

4. The method of claim 1, wherein the conductor layer is mainly made of tungsten.

5. The method of claim 1, wherein the conductor layer is formed by sputtering a first metal layer on the front surface of the ceramic substrate using physical vapor deposition technology then plating a second metal layer on the first metal layer using chemical vapor deposition.

6. The method of claim 1, wherein the redistribution lines consist essentially of copper.

7. The method of claim 6, in which after the redistribution lines are pattered the method further comprises:
plating a precious metal layer on the front surface of the ceramic substrate including the redistribution lines;
plating an adhering layer on the precious metal layer;
patterning the adhering layer into junction pads each having a surface area substantially identical to a footprint of a micro probe to be formed; and
patterning the adhering layer into shapes covering the redistribution lines.

8. The method of claim 1, wherein the dry etch mask layer is mainly tungsten.

9. The method of claim 1, wherein the metal deposited in the vertical cavities is mainly nickel.

10. The method of claim 9, wherein the metal deposited in the vertical cavities consists essentially of nickel and tungsten.

11. The method of claim 9, wherein the metal deposited in the vertical cavities is composed of nickel and cobalt.

12. The method of claim 1, wherein a tapered top portion of the metal deposited in the vertical cavities is further plated with rhodium.

13. The method of claim 1, further comprising a fast annealing process to the ceramic substrate comprising the micro probes.
